(19) United States
(12) Patent Application Publication
(10) Pub. No.: US 2024/0357913 A1
(43) Pub. Date: Oct. 24, 2024

(54) BANK TRANSMISSION PATTERN OF COLOR CONVERSION PANEL, DISPLAY DEVICE INCLUDING THE SAME, AND METHOD OF PROVIDING THE SAME

(71) Applicant: Samsung Display Co., LTD., Yongin-si (KR)

(72) Inventors: Young Min KIM, Yongin-si (KR); Hyun-Seok KIM, Yongin-si (KR); Hyeong Gyu KIM, Yongin-si (KR); Hyo Joon KIM, Yongin-si (KR); Hyun Woo NOH, Yongin-si (KR); Keun Young PARK, Yongin-si (KR); Moon Jung BAEK, Yongin-si (KR); Hye Seung LEE, Yongin-si (KR)

(21) Appl. No.: 18/442,641

(22) Filed: Feb. 15, 2024

(30) Foreign Application Priority Data
Apr. 19, 2023 (KR) 10-2023-0051504

(51) Int. Cl. H10K 59/80; H10K 59/12; H10K 59/38

(52) U.S. Cl. CPC H10K 59/8792; H10K 59/1201; H10K 59/38

(57) ABSTRACT

A color conversion panel includes a substrate including first and second light emitting regions, banks partitioning the first and second light emitting regions, each bank among the banks including a bank light transmission layer, a metal layer on the bank light transmission layer and a transparent layer on the metal layer, a color conversion layer in the first light emitting region, and a light transmission layer in the second light emitting region. The bank light transmission layer and the light transmission layer are respective portions of a same material layer on the substrate.

This application claims priority to Korean Patent Application No. 10-2023-0051504 filed on Apr. 19, 2023, and all the benefits accruing therefrom under 35 U.S.C. § 119, the entire contents of which are incorporated herein by reference.

### BACKGROUND

### (a) Field

The present disclosure relates to a color conversion panel, a display device including the same, and a method of manufacturing (or providing) the same.

### (b) Description of the Related Art

In a light emitting device, holes supplied from an anode and electrons supplied from a cathode are combined in an emission layer between the anode and the cathode, to form excitons, and the excitons emit light while being stabilized.

Since the light emitting device has various merits such as a wide viewing angle, fast response speed, thin thickness and low power consumption, it is widely applied to various electric and electronic devices such as televisions, monitors and mobile phones.

A display device including a color conversion panel has been proposed to implement a high-efficiency display device.

The color conversion panel converts or transmits incident light into different colors.

The incident light is mainly blue light, and the blue light is converted into both red and green, or is transmitted as blue light without color change or color-conversion.

### SUMMARY

Embodiments provide a color conversion panel that prevents color mixing between light emitting regions and improves light efficiency, a display device including the same, and a method of providing thereof.

A color conversion panel according to an embodiment of the present invention includes a substrate, a plurality of banks positioned on the substrate and including a first light emitting region, a second light emitting region, and a third light emitting region, a first color conversion layer positioned in said first light emitting region, a second color conversion layer positioned in the second light emitting region, and a light transmitting layer positioned in the third light emitting region, where the bank includes a first bank and a second bank, the bank includes a bank transmission layer, a metal layer covering the bank transmission layer, and a transparent layer covering the metal layer, where the bank transmission layer and the emission layer positioned in the third light emitting region are positioned in the same layer and include the same material.

In the bank, the bank transmission layer may be positioned closest to the substrate, and the transparent layer may be positioned farthest from the substrate.

A bank transmission layer included in a second bank adjacent to the third light emitting region may be integrally formed with a light transmission layer of the third light emitting region.

The metal layer may not overlap the first light emitting region, the second light emitting region, and the third light emitting region in a direction vertical to the substrate.

The metal layer may have a thickness of about 100 angstroms (Å) to about 1000 Å.

The transparent layer may have a thickness of about 1 micrometer (μm) to about 5 micrometers (μm).

In the first bank positioned between the first light emitting region and the second light emitting region, the metal layer may cover the entire surface of the bank transmission layer, and the transparent layer may cover the entire surface of the metal layer.

In the second bank adjacent to the third light emitting region, the upper surface and one side surface of the bank transmission layer may be covered by the metal layer, and the transparent layer may cover the metal layer.

The entire metal layer may be positioned to overlap the transparent layer.

The first light emitting region may emit red light, the second light emitting region may emit green light, and the third light emitting region may emit blue light.

A method of manufacturing (or providing) a display device according to an embodiment includes forming a plurality of bank transmission layers and a light transmission layer spaced apart from each other on a substrate, forming a metal layer on the bank transmission layer and the light transmission layer, and a partial region of the metal layer forming a transparent layer, and forming a bank including a bank transmission layer, a metal layer, and a transparent layer by etching a metal layer that does not overlap with the transparent layer.

The method may further include forming a first color conversion layer and a second color conversion layer in the regions between the banks.

The bank transmission layer may be integrally formed with the light transmission layer, the metal layer may cover an upper surface and one side of the bank transmission layer, and the transparent layer may cover the metal layer.

The bank includes a first bank and a second bank, and in the first bank positioned between the first color conversion layer and the second color conversion layer, the metal layer covers the entire surface of the bank transmission layer, and the transparent layer may cover the entire surface of the metal layer.

The method may further include forming color filters on the substrate before forming the plurality of bank transmission layers and the light transmission layer spaced apart from each other on the substrate.

The method may further include forming a plurality of transistors and light emitting devices connected thereto on the substrate before forming the plurality of bank transmission layers and the light transmission layer spaced apart from each other on the substrate.

A display device according to an embodiment includes a color conversion panel and a display panel overlapping the color conversion panel, where the display panel includes a first substrate, a plurality of partition walls disposed on the first substrate, and between the partition walls. The color conversion panel includes a second substrate, a plurality of banks positioned on the second substrate and partitioning the first light emitting region, the second light emitting region, and the third light emitting region, and a plurality of banks in the first light emitting region, a first color conversion layer positioned in the second light emitting region, a second color conversion layer positioned in the second light emitting region, and a light transmission layer positioned in the third light emitting region, where the banks cover the bank transparent layer and the bank transparent layer and a transparent layer covering the metal layer, and the bank transmission layer included in the bank and the light transmission layer positioned in the third light emitting region are positioned on the same layer and include the same material.

The entire metal layer may overlap the transparent layer, but the metal layer may not overlap the first light emitting region, the second light emitting region, and the third light emitting region.

A display device according to another embodiment includes a first substrate, a plurality of partition walls disposed on the first substrate, an emission layer disposed between the partition walls, a first light emitting region overlapping the partition walls, a first light emitting region, a second light emitting region, and a second light emitting region. There are three banks partitioning the light emitting region, a first color conversion layer positioned in the first light emitting region, a second color conversion layer positioned in the second light emitting region, and a light transmitting layer positioned in the third light emitting region. The bank includes a bank transmission layer, a metal layer covering the bank transmission layer, and a transparent layer covering the metal layer, and the bank transmission layer included in the bank and the light transmission layer positioned in the third light emitting region are in the same layer and contain the same material.

The entire metal layer may overlap the transparent layer, but the metal layer may not overlap the first light emitting region, the second light emitting region, and the third light emitting region.

According to embodiments, a color conversion panel preventing color mixing and improving light efficiency, a display device including the same, and a manufacturing method thereof are provided.

### BRIEF DESCRIPTION OF THE DRAWINGS

The above and other advantages and features of this disclosure will become more apparent by describing in further detail embodiments thereof with reference to the accompanying drawings, in which:

FIG. 1 shows a cross-sectional view of a color conversion panel according to the present embodiment.

FIG. 2 to FIG. 4 respectively show patterns of a blue color filter, a red color filter, and a green color filter.

FIG. 5 is an enlarged view of a region indicated by B in FIG. 1, and illustrates a bank.

FIG. 6 is an enlarged view of a region indicated by C in FIG. 1, and shows a bank positioned adjacent to a blue light emitting region.

FIG. 7 is a cross-sectional view of a display device including a color conversion panel according to an embodiment.

FIG. 8 is a cross-sectional view of a display device including a color conversion panel according to an embodiment.

FIG. 9 to FIG. 13 illustrate cross-sectional views of process structures in a method of manufacturing (or providing) the color conversion panel according to the embodiment of FIG. 1.

FIG. 14 to FIG. 18 illustrate cross-sectional views of process structures in a method of manufacturing (or providing) the display device according to the embodiment of FIG. 8.

### DETAILED DESCRIPTION

Hereinafter, with reference to the accompanying drawings, various embodiments of the present invention will be described in detail so that a person of an ordinary skill in the art could easily carry out the present invention.

The present invention may be embodied in many different forms, and is not limited to the embodiments set forth herein.

In order to clearly describe the present invention, parts irrelevant to the description are omitted, and the same reference numerals are assigned to the same or constituent elements throughout the specification. Within the Figures and the text of the disclosure, a reference number indicating a singular form of an element may also be used to reference a plurality of the singular element.

In addition, since the size and thickness of each component shown in the drawings are arbitrarily shown for convenience of explanation, the present invention is not necessarily limited to what is shown.

In the drawings, the thickness is shown enlarged to clearly express the various layers and regions.

And in the drawings, for convenience of explanation, the thicknesses of some layers and regions are exaggerated.

In addition, when a part such as a layer, film, region, plate, etc. is said to be related to another element such as being “above” or “on” another part, this includes not only the case where the part is “directly on” the other part, but also the case where another part is in the middle.

Conversely, when a part is said to be related to another element such as being “directly on” another part, it means that there is no other part in between.

In addition, being “above” or “on” a reference part means being positioned above or below the reference part, and does not necessarily mean being positioned “above” or “on” in the opposite direction of gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise,” and variations such as “comprises” or “comprising,” will be understood to imply the inclusion of stated elements but not the exclusion of any other elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, throughout the specification, when referring to “planar image,” it means when the target part is viewed from above, and when referring to “cross-sectional image,” it means when a cross-section of the target part cut vertically is viewed from the side.

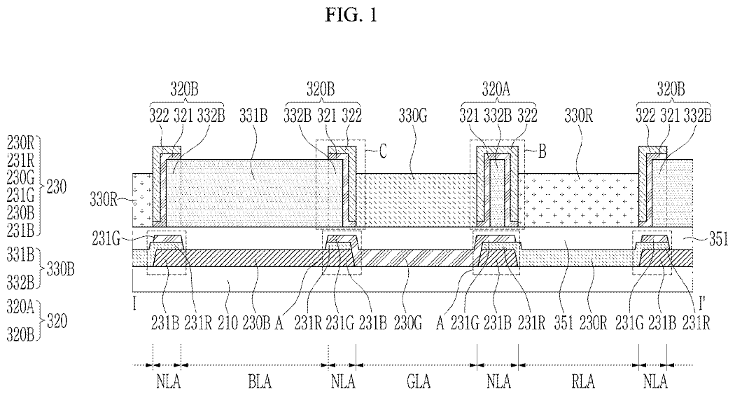

FIG. 1 shows a color conversion panel (200) according to the present embodiment.

Referring to FIG. 1, the color conversion panel (200) according to the present embodiment includes a second substrate (210), a color filter (230) as a color filter layer positioned on the second substrate (210), and a color conversion layer, in order along a thickness direction of the color conversion panel (200). The color conversion layer includes a bank (320) of a first bank layer which is provided in plural including banks (320) arranged along the second substrate (210), together with a plurality of patterns respective disposed between the banks (320). The plurality of patterns includes a light transmission layer (331B) as a light transmission pattern, a red color conversion layer (330R) as a first color conversion pattern, and a green color conversion layer (330G) as a second color conversion pattern.

Although described in detail later, the bank (320) may include a bank transmission layer (332B) therein. The light transmission pattern (e.g., the light transmission layer (331B)) may extend to define an extended portion of the light transmission pattern, and the extended portion includes or defines the bank transmission layer (332B) of a respective bank (320). That is, in the present embodiment, the light transmission layer (331B) and the bank transmission layer (332B) may be formed by the same process in a method of providing the color conversion panel (200) and include the same material. As used herein, where elements are described as being in a same layer as each other, the elements may be formed in a same process and/or include a same material as each other, the elements may be respective portions of a same material layer, the elements may be on a same layer by forming an interface with a same underlying or overlying layer, etc., without being limited thereto.

The color conversion panel (200) of FIG. 1 may overlap a display panel (100).

The color conversion panel (200) of FIG. 1 may be positioned such that the second substrate (210) faces the first substrate (not shown) of the display panel (100), and light emitted from the display panel (100) as a light source to the color conversion panel (200), is transmitted through the color conversion layers (330R, 330G) of the color conversion panel (200) and/or the light transmission layer (331B), passes through the color filter (230), and passes through the second substrate (210) in order, to be emitted to outside the color conversion panel (200) at the second substrate (210).

Hereinafter, the configuration of the color conversion panel (200) according to the embodiment of FIG. 1 will be described in detail.

A color filter (230) includes a plurality of patterns including a blue color filter (230B), a red color filter (230R), and a green color filter (230G) is positioned on the second substrate (210).

Referring to FIG. 1, a blue dummy color filter (231B) is positioned on (or in) the same layer as the blue color filter (230B).

The blue color filter (230B) may be positioned in the blue light emitting region (BLA), and the blue dummy color filter (231B) may be positioned in the non-emission region (NLA) which is adjacent to the blue light emitting region (BLA) and overlapping the bank (320). The non-emission region (NLA) may be a portion or planar area of the color conversion panel (200) except for the planar area of the light emitting regions.

In FIG. 1, the blue color filter (230B) and the blue dummy color filter (231B) are shown as separate components, but may be actually connected. That is, the blue color filter (230B) may extend to define an extended portion thereof, and the extended portion includes or defines the blue dummy color filter (231B) of the non-emission region (NLA).

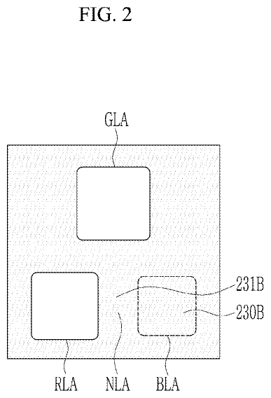

FIG. 2 to FIG. 4 respectively show patterns of a blue color filter (230B), a red color filter (230R), and a green color filter (230G).

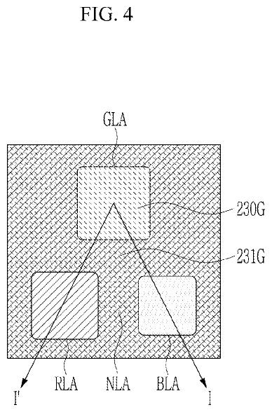

A cross section cut along line I-I′ in FIG. 4 may correspond to FIG. 1.

Referring to FIG. 2, portions of a blue color filter layer are positioned in all regions along the second substrate (210), except for the green light emitting region (GLA) and the red light emitting region (RLA). The blue color filter layer (230B and 231B together) may define a first opening which exposes an underlying layer such as the second substrate (210), to outside the blue color filter layer. The first opening may be provided in plural including first openings respectively corresponding to the green light emitting region (GLA) and the red light emitting region (RLA).

Within the blue color filter layer, the blue color filter (230B) is positioned in the blue light emitting region (BLA) and the blue dummy color filter (231B) is positioned in the non-emission region (NLA). Each pattern of the blue color filter layer may include outer edges which define a planar shape of the pattern.

In FIG. 1, both edges of the blue color filter (230B) which oppose each other are in the non-emission region (NLA) overlapping the bank (320), and the blue dummy color filter (231B) defines the outer edges opposing each other. It will be understood that while FIG. 1 shows a thickness of layers and components (e.g., a vertical direction in FIG. 1) along a first direction (e.g., the horizontal direction in FIG. 1), a same or similar construction may be arranged along a second direction (e.g., into the view of FIG. 1) crossing both the first direction and the thickness direction. Here, the first and second directions which cross each other may define a plane, while the vertical direction in FIG. 1 defines a third direction as a thickness direction.

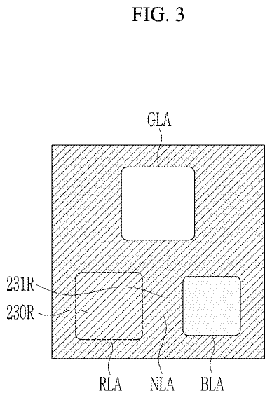

Next, referring to FIG. 1 and FIG. 3 simultaneously, a red color filter layer including a red color filter (230R) and a red dummy color filter (231R) is positioned on the blue color filter layer including the blue color filter (230B) and the blue dummy color filter (231B).

Referring to FIG. 3, the red color filter layer is positioned in all regions except for the green light emitting region (GLA) and the blue light emitting region (BLA). The red color filter layer (230R and 231R together) may define a second opening which exposes an underlying layer to outside the red color filter layer. The second opening may be provided in plural including second openings respectively corresponding to the green light emitting region (GLA) and the blue light emitting region (BLA). Referring to FIG. 3, the second substrate (210) and the blue color filter layer may be exposed to outside the red color filter layer at the green light emitting region (GLA) and the blue light emitting region (BLA), respectively.

Within the red color filter layer, the red color filter (230R) is positioned in the red emission region (RLA) and the red dummy color filter (231R) is positioned in the non-emission region (NLA).

In FIG. 1, both edges of the red color filter (230R) which oppose each other are the non-emission region (NLA) overlapping the bank (320), and the red dummy color filter (231R) defines the outer edges opposing each other.

Next, referring to FIG. 1 and FIG. 4 simultaneously, a green color filter layer including a green color filter (230G) and a green dummy color filter (231G) is positioned on the blue color filter layer including a blue color filter (230B) and a blue dummy color filter (231B), and on a red color filter layer including a red color filter (230R) and a red dummy color filter (231R). That is, the blue color filter layer as a first color filter layer, the red color filter layer as a second color filter layer, and the green color filter layer as a third color filter layer may be provided or formed in order, on the second substrate (210).

Referring to FIG. 4, the green color filter layer is positioned in all regions except for the blue light emitting region (BLA) and the red light emitting region (RLA). The green color filter layer (230G and 231G together) may define a third opening which exposes an underlying layer to outside the green color filter layer. The third opening may be provided in plural including third openings respectively corresponding to the red light emitting region (RLA) and the blue light emitting region (BLA). Referring to FIG. 4, the red color filter layer and the blue color filter layer may be exposed to outside the green color filter layer at the red light emitting region (RLA) and the blue light emitting region (BLA), respectively

Within the green color filter layer, the green color filter (230G) is positioned in the green light emitting region (GLA) is, and the green dummy color filter (231G) is positioned in the non-emission region (NLA).

In FIG. 1, both edges of the green color filter (230G) which oppose each other are in the non-emission region (NLA) overlapping the bank (320), and the green dummy color filter (231G) defines the outer edges opposing each other.

Referring to FIG. 1, a blue dummy color filter (231B), a red dummy color filter (231R), and a green dummy color filter (231G) overlap each other in a region overlapping (or corresponding to) the bank (320).

The blue dummy color filter (231B), the red dummy color filter (231R), and the green dummy color filter (231G) overlap each other to form a color filter overlapping body (A) within the color filter layer.

The color filter overlapping body (A) may function in the same way as a light blocking layer.

That is, the color filter overlapping body (A) may block light in the non-emission region (NLA).

In this case, the blue dummy color filter (231B) may be positioned closer to the second substrate (210) than each of the red dummy color filter (231R) and the green dummy color filter (231G).

The direction in which an image is viewable from outside the color conversion panel (200), such as by a user which views the image, is toward the second substrate (210) from the color filter layer. Here, the blue dummy color filter (231B) may be positioned at the side from which the image is viewed.

The blue color filter layer may be positioned closest to the side from which the image is viewed since, compared to green or red, blue has the lowest reflectance of entire light (e.g., external light) and can block light from outside the color conversion panel (200) most effectively.

Referring to FIG. 1, a low refractive index layer (351) may be positioned on the color filter (230). The color filter layer may face the color conversion layer with the low refractive index layer (351) therebetween.

The low refractive index layer (351) may have a refractive index of about 1.2 or less.

The low refractive index layer (351) may include a combination of an organic material and an inorganic material.

However, the refractive index and material are only examples, and the low refractive index layer (351) is not limited thereto.

Referring to FIG. 1, a bank (320) within the color conversion layer is positioned overlapping the color filter overlapping body (A).

As shown in FIG. 1, the bank (320) may include a bank transmission layer (332B), a metal layer (321) and a transparent layer (322).

The bank (320) may be provided in plural including a first bank (320A) and a second bank (320B) having different shapes from each other. The shapes may be taken in cross-section and/or in a planar view.

The structure of the bank (320) will be separately described later in detail.

Within the color conversion layer on the second substrate (210), a red color conversion layer (330R) as the first color conversion pattern, a green color conversion layer (330G) as the second color conversion pattern, and a light transmission layer (331B) are respectively positioned in a region between the banks (320) adjacent to and spaced apart from each other.

In FIG. 1, a red color conversion layer (330R) is positioned in a region overlapping the red light emitting region (RLA).

The red color conversion layer (330R) may convert supplied light (e.g., incident light of a first color) into red light having a different color from the first color.

Similarly, the green color conversion layer (330G) is positioned in a region overlapping the green light emitting region (GLA).

The green color conversion layer (330G) may convert supplied light having the first color into green light having a different color from the first color.

In an embodiment, the red color conversion layer (330R) and the green color conversion layer (330G) may include different semiconductor nanocrystals.

The semiconductor nanocrystals may include at least one of a phosphor and a quantum dot material that converts incident light into red or green.

A size, such as a diameter of the quantum dots may be, for example, about 1 nanometer (nm) to about 10 nanometers (nm).

In a method of providing the color conversion panel (200), the quantum dots may be synthesized by a wet chemical process, an organometallic chemical vapor deposition process, a molecular beam epitaxy process, or a process similar thereto.

The wet chemical process is a method of growing quantum dot particle crystals after combining an organic solvent and a precursor material.

When the crystal grows, the organic solvent naturally acts as a dispersant coordinated on the surface of the quantum dot crystal and controls the growth of the crystal, The growth of quantum dot particles can be controlled through a process that is easier and cheaper than vapor deposition methods such as epitaxy.

Quantum dots include group III-VI semiconductor compounds, group II-VI semiconductor compounds, group III-V semiconductor compounds, group III-VI semiconductor compounds, group I-III-VI semiconductor compounds, group IV-VI semiconductor compounds, group IV elements or compounds, or any combination thereof.

Examples of group II-VI semiconductor compounds include binary element compounds such as CdS, CdSe, CdTe, ZnS, ZnSe, ZnTe, ZnO, HgS, HgSe, HgTe, MgSe, MgS and the like, ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like, quaternary compounds such as CdZnSeS, CdZnSeTe, CdZnSTe, CdHgSeS, CdHgSeTe, CdHgSTe, HgZnSeS, HgZnSeTe, HgZnSTe and the like, or any combination thereof.

Examples of group III-V semiconductor compounds include binary element compounds such as GaN, GaP, GaAs, GaSb, AlN, AlP, AlAs, AlSb, InN, InP, InAs, InSb, and the like, ternary compounds such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and the like, quaternary compounds such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and the like, or any combination thereof.

The group III-V semiconductor compounds may further include a group II element.

Examples of the group III-V semiconductor compounds further include a group II element may include InZnP, InGaZnP, InAlZnP, and the like.

Examples of the group III-VI semiconductor compounds may include binary element compounds such as GaS, Ga2S3, GaSe, Ga2Se3, GaTe, InS, InSe, In2Se3, InTe, and the like, ternary compounds such as InGaS3 and InGaSe3, or any combination thereof.

Examples of the group I-III-VI semiconductor compounds may include ternary compounds such as AgInS, AgInS2, AgInSe2, AgGaS, AgGaS2, AgGaSe2, CuInS, CuInS2, CuInSe2, CuGaS2, CuGaSe2, CuGaO2, AgGaO2, AgAlO2, and the like, quaternary compounds such as AgInGaS2 and AgInGaSe2, and the like, or any combination thereof.

Examples of the group IV-VI semiconductor compounds include binary element compounds such as SnS, SnSe, SnTe, PbS, PbSe, PbTe, and the like, ternary compounds such as SnSeS, SnSeTe, SnSTe, PbSeS, PbSeTe, PbSTe, SnPbS, SnPbSe, SnPbTe, and the like, quaternary compounds such as SnPbSSe, SnPbSeTe, SnPbSTe, and the like, or any combination thereof.

Group IV elements or compounds include single-element compounds such as Si, Ge, and the like, binary element compounds such as SiC, SiGe, and the like, or any combination thereof.

Each element included in a multi-element compound such as a binary element compound, a ternary element compound, and a quaternary element compound may be present in a particle at a uniform concentration or a non-uniform concentration.

That is, the chemical formula means the types of elements included in the compound, and the element ratios in the compound may be different.

For example, AgInGaS2 may mean AgInxGa1-xS2 (x is a real number between 0 and 1).

On the other hand, the quantum dot may have a single structure in which the concentration of each element included in the quantum dot is uniform or a dual core-shell structure.

For example, a material included in the core and a material included in the shell may be different from each other.

The shell of the quantum dots may serve as a protective layer for maintaining semiconductor properties by preventing chemical denaturation of the core and/or as a charging layer for imparting electrophoretic properties to the quantum dots.

The shell may be monolayer or multilayer.

The interface between the core and the shell may have a concentration gradient in which the concentration of elements present in the shell decreases toward the center.

Examples of the quantum dot shell include oxides of metals or non-metals, semiconductor compounds, or combinations thereof.

Examples of oxides of metals or nonmetals include binary element compounds such as SiO2, Al2O3, TiO2, ZnO, MnO, Mn2O3, Mn3O4, CuO, FeO, Fe₂O₃, Fe₃O₄, CoO, Co3O4, NiO, and the like, ternary compounds such as MgAl2O4, CoFe2O4, NiFe2O4, CoMn2O4 and the like, or any combination thereof.

Examples of semiconductor compounds include the group III-VI semiconductor compounds, as described herein, group II-VI semiconductor compounds, group III-V semiconductor compounds, group III-VI semiconductor compounds, group I-III-VI semiconductor compounds, group IV-VI semiconductor compounds, or any combination thereof.

For example, the semiconductor compound is CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or any combination thereof.

Each element included in a multi-element compound such as a two-element compound or a three-element compound may be present in a particle at a uniform or non-uniform concentration.

That is, the chemical formula means the types of elements included in the compound, and the element ratios in the compound may be different.

Quantum dots may have a full width of half maximum (FWHM) of the emission wavelength spectrum of about 45 nm or less, specifically about 40 nm or less, more specifically about 30 nm or less, and in this range, color purity or color reproducibility can be improved.

In addition, since light emitted through the quantum dots in all directions, a wide viewing angle may be improved.

In addition, the shape of the quantum dots may be specifically spherical, pyramidal, multi-arm, or cubic nanoparticles, nanotubes, nanowires, nanofibers, nanoplatelet particles, and the like.

Since the energy band gap can be controlled by adjusting the size of the quantum dots or the ratio of elements in the quantum dot compound, light of various wavelengths can be obtained from the quantum dot emission layer.

Therefore, by using quantum dots (using quantum dots of different sizes or having different element ratios in a quantum dot compound) as described above, a light emitting device emitting light of various wavelengths can be implemented.

Specifically, control of the size of the quantum dots or the ratio of elements in the quantum dot compound may be selected to emit red, green, and/or blue light.

In addition, the quantum dots may be configured to emit white light by combining light of various colors.

Referring back to FIG. 1, a color converting material or pattern of the color conversion layer is not positioned in a portion corresponding to the blue light emitting region (BLA) at a respective space partitioned by the bank (320).

As shown in FIG. 1, the bank (320) includes a first bank (320A) and a second bank (320B), and the stacked structures of the first bank (320A) and the second bank (320B) are different.

The second bank (320B) is positioned adjacent to and/or closest to the blue light emitting region (BLA). The bank transmission layer (332B) included in the second bank (320B) is connected to the light transmission layer (331B) of the blue light emitting region (BLA). As being connected, the transmission material portions (331B and 332B) may contact each other to form an interface therebetween, one element may be an extended portion of another element to define an unitary pattern, etc. For illustration purposes, a boundary between the transmission material portions (331B and 332B) is indicated by a dotted line in FIG. 1.

The light transmission layer (331B) and the bank transmission layer (332B) may include scatterers which scatter or disperse light transmitted therethrough (e.g., a light scatterer or a light scattering material).

The scattering material may be at least one selected from the group consisting of SiO2, BaSO4, Al2O3, ZnO, ZrO2 and TiO2.

The light transmission layer (331B) and the bank transmission layer (332B) may be formed through the same process and include the same material.

Hereinafter, the light transmission layer (331B) and the bank transmission layer (332B) are referred to as a transmission layer (330B).

The transmission layer (330B) may include a polymer resin and a scattering material which is included in the polymer resin.

For example, the transmission layer (330B) may include TiO2, but is not limited thereto.

The transmission layer (330B) may transmit light incident to the color conversion panel (200) from the display panel (100), without color change or color-conversion at the color conversion panel (200).

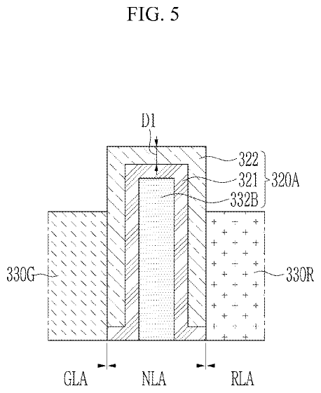

FIG. 5 is an enlarged view of the region indicated by B in FIG. 1 and shows the first bank (320A).

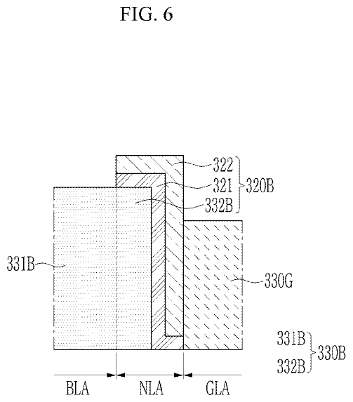

FIG. 6 is an enlarged view of the region indicated by C in FIG. 1 and shows the second bank (320B) positioned adjacent to the blue light emitting region (BLA), such as at opposing sides thereof in one direction, or surrounding the blue light emitting region (BLA) in the plan view.

Referring to FIG. 5, a bank transmission layer (332B) of a transmission layer pattern which is positioned at the innermost area of the first bank (320A). The innermost area may include a center of the first bank (320A) in the plan view.

Referring to FIG. 6, the light transmission layer (331B) of the transmission layer pattern which is positioned in the blue light emitting region (BLA) is connected to and extends from the bank transmission layer (332B) in the non-emission region (NLA).

That is, the light transmission layer (331B) and the bank transmission layer (332B) of the transmission layer pattern may be integrally formed as a unitary pattern.

Referring back to FIG. 5 and FIG. 6, the metal layer (321) is positioned on the bank transmission layer (332B).

In the first bank (320A) of FIG. 5, the metal layer (321) may be positioned to cover the entire bank transmission layer (332B). That is, the metal layer (321) may extend along side surfaces of the bank transmission layer (332B) and along a top surface thereof which is furthest from the second substrate (210). The metal layer (321) may be extended around an entirety of the side surfaces to surround the bank transmission layer (332B) in the plan view.

Referring to FIG. 6, in the second bank (320B) adjacent to the blue light emitting region (BLA), the metal layer (321) may cover only a partial region of the bank transmission layer (332B). The metal layer (321) may extend along a sidewall of the bank transmission layer (332B) which is closest to a color conversion pattern, and along a top surface of the bank transmission layer (332B). The top surface portion of the metal layer (321) may terminate at a boundary between the non-emission region (NLA) and the blue light emitting region (BLA).

That is, in the blue light emitting region (BLA), the metal layer (321) does not cover the bank transmitting layer (332B), and in the non-emission region (NLA), the metal layer (321) can cover the sides and top surface of the bank transmitting layer (332B). That is, an upper surface of the light transmission layer (331B) is exposed to outside the metal layer (321) of the second bank (320B), at the blue light emitting region (BLA).

A thickness of the metal layer (321) and the transparent layer (322) are defined in a direction normal to an underlying surface, such as the outer surface of the bank transmission layer (332B). The thickness of the metal layer (321) may be between about 100 angstroms (Å) and about 1000 Å.

The metal layer (321) may include one or more of Al, Cu, and Ag, but is not limited thereto.

Referring to FIG. 5, in the first bank (320A), the transparent layer (322) may be positioned to cover the entire metal layer (321), such as by extending along the side surfaces and the top surface of the metal layer (321.

That is, as shown in FIG. 5, in the first bank (320A), the bank transmission layer (332B) may be covered at both the top and sides by the metal layer (321), and both the top and sides of the metal layer (321) may be covered by the transparent layer (322).

A thickness D1 of the transparent layer (322) may be 1 micrometer (μm) to about 5 micrometers (μm).

Referring to FIG. 6, the transparent layer (322) is positioned in the second bank (320B) adjacent to the blue light emitting region (BLA).

The transparent layer (322) may be positioned to overlap the metal layer (321).

As shown in FIG. 6, in the second bank (320B), the transparent layer (322) may not be positioned in the blue light emitting region (BLA). That is, the top surface portion of transparent layer (322) may terminate at the boundary between the non-emission region (NLA) and the blue light emitting region (BLA).

The transparent layer (322) may be positioned to overlap the top and side surfaces of the bank transmission layer (332B) in the non-emission region (NLA).

As shown in FIG. 1 and FIG. 6, the edge of the transparent layer (322) coincides with the edge of the metal layer (321) in the second bank (320B).

That is, the edge of the transparent layer (322) and the edge of the metal layer (321) are aligned. A distal end of the transparent layer (322) which is furthest from the respective color conversion pattern may be coplanar with a distal end of the metal layer (321), without being limited thereto.

Although this will be separately described later, the end surfaces of the transparent layer (322) and the metal layer (321) are aligned with each other since the metal layer (321) is etched using the transparent layer (322) as a mask during a method of manufacturing or providing the color conversion panel (200).

As such, in the color conversion panel (200) according to the present embodiment, the bank (320) includes a bank transmission layer (332B) as a transmission pattern of the color conversion layer, a metal layer (321), and a transparent layer (322).

In this case, the bank transmission layer (332B) is formed of or includes the same material as the light transmission layer (331B) of the blue light emitting region (BLA) and may be formed in the same process as the light transmission layer (331B). The bank transmission layer (332B) is provided in plural including a plurality of bank transmission layers (332B) spaced apart from each other.

Therefore, the bank transmission layer (332B) and the light transmission layer (331B) as respective portions of the transmission pattern layer can be applied to a high-resolution display device.

The pattern portions of the transmission pattern layer described above can be applied to a high-resolution display device since a distance between adjacent light emitting regions in a direction along the color conversion panel (200) can be reduced compared to a conventional structure where the transmission layer (330B) and the conventional bank which defines or is closest to the blue light emitting region (BLA) are formed (or provided) through separate processes.

In addition, since the metal layer (321) is included in the present embodiment, light emitted from each respective light emitting region is reflected by a sidewall of the metal layer (321) which faces the respective light emitting region, to increase luminous efficiency.

That is, light incident to the bank (320) from a respective color conversion or transmission pattern at a light emitting region, may be reflected by the metal layer (321) and then incident again into the light emitting region.

The transparent layer (322) positioned on the metal layer (321) may define an outermost surface of the bank (320) and be used as a mask for forming the metal layer (321).

When the conventional bank includes a black material, light absorption occurs in the conventional bank, and thus light emission efficiency may decrease.

Also, when the conventional bank includes a transparent material, color mixing may occur between adjacent light emitting regions.

However, in the display device according to the present embodiment, since the bank (320) includes the bank transmission layer (332B) together with the metal layer (321) and the transparent layer (322), color mixing is prevented and efficiency is increased.

Table 1 below shows light efficiency measured while varying a thickness of the transparent layer (322) of the bank (320) according to the present embodiment.

In this case, the relative efficiency was described by taking the efficiency when the bank (320) includes the black material as 100%.

TABLE 1

| | bank transparent layer thickness | | |
|---|---|---|---|
| | 3 μm | 4 μm | 5 μm |
| efficiency | 141% | 137% | 133% |

As can be seen from Table 1, when the thickness of the transparent layer (322) is 3 μm to 5 μm, a display device including the color conversion panel (200) having the bank (320) according to the present embodiment has improved efficiency compared to a conventional display device including the black conventional bank.

As can be seen in Table 1, the efficiency increased as the thickness of the transparent layer (322) of the bank (320) decreased.

Considering the process, the minimum thickness of the bank (320) may be about 1 μm or more.

A display device including the color conversion panel (200) according to the present embodiment will be described below.

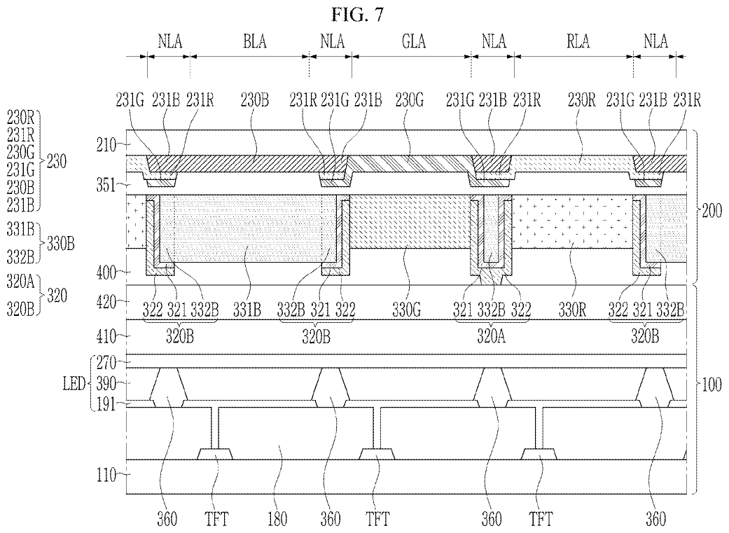

FIG. 7 is a cross-sectional view of a display device including a color conversion panel (200) according to the present embodiment.

Referring to FIG. 7, the display device according to the present embodiment includes a display panel (100) and a color conversion panel (200).

A description of the color conversion panel (200) is the same as that of FIG. 1, so it is omitted.

The display panel (100) includes a first substrate (110), a plurality of transistors (TFT) positioned on the first substrate (110), and an insulating layer (180).

A first electrode (191) and a partition wall (360) of a display element layer are positioned in the insulating layer (180). The first electrode (191) is positioned in an opening of the partition wall (360) and is connected to the transistor (TFT) of a display circuit layer.

Although not specifically illustrated, the transistor (TFT) may include a semiconductor layer, a source electrode and a drain electrode connected to the semiconductor layer, and a gate electrode insulated from the semiconductor layer, within the display circuit layer.

The second electrode (270) is positioned on the partition wall (360) and the light emitting device layer (390) is positioned between the first electrode (191) and the second electrode (270).

The first electrode (191), the second electrode (270), and the light emitting device layer (390) are collectively referred to as a light emitting device (LED) (e.g., light emitting element of the display element layer).

The plurality of light emitting devices (LEDs) may emit light of different colors or may emit light of the same color.

For example, the light emitting device (LED) may emit red, green, and blue light.

Alternatively, the light emitting device (LED) may emit blue light and green light.

The light emitting device (LED) may have a structure in which light emitting devices emitting different colors are stacked, such as along a thickness direction.

For example, in the light emitting device (LED), an emission layer emitting blue light and a light emitting layer emitting green light may be stacked.

Alternatively, light emitting layers emitting blue light/green light/red light may be stacked.

The partition wall (360) which is provided in a second bank layer, may include a black material to prevent color mixing between adjacent light emitting devices (LEDs).

In FIG. 7, an encapsulation layer (410) may be positioned on the light emitting device (LED) of the display panel (100).

The encapsulation layer (410) may have a multilayer structure in which organic layers and inorganic layers are alternately stacked.

Among the multi-layered encapsulation layers (410), a layer positioned farthest from the first substrate (110) may include SiON.

A buffer layer (420) may be positioned between the encapsulation layer (410) and a first insulating layer (400).

The buffer layer (420) may combine the display panel (100) and the color conversion panel (200) to each other.

The buffer layer (420) may include an organic material.

The refractive index of the buffer layer (420) may be about 1.6 to about 1.7.

This refractive index is an excellent refractive index range in which extraction efficiency of light emitted from the display panel (100) is the highest.

Depending on the embodiment, the buffer layer (420) may be omitted.

In FIG. 7, the first insulating layer (400) positioned on the color conversion panel (200) may be included.

The first insulating layer (400) is a layer for capping the red color conversion layer (330R) and the transmission layer (330B).

The first insulating layer (400) may include SiON.

The thickness of the first insulating layer (400) may be about 3500 Å to about 4500 Å.

The refractive index of the first insulating layer (400) may be about 1.4 to about 1.6.

The first insulating layer (400) may include an inorganic material.

However, this is just an example, and the first insulating layer (400) may include an organic material and may be omitted or multi-layered according to embodiments.

In FIG. 7, the display device including the first substrate (110) of the display panel (100) and the second substrate (210) of the color conversion panel (200) has been described, but according to an embodiment, the display device includes one substrate.

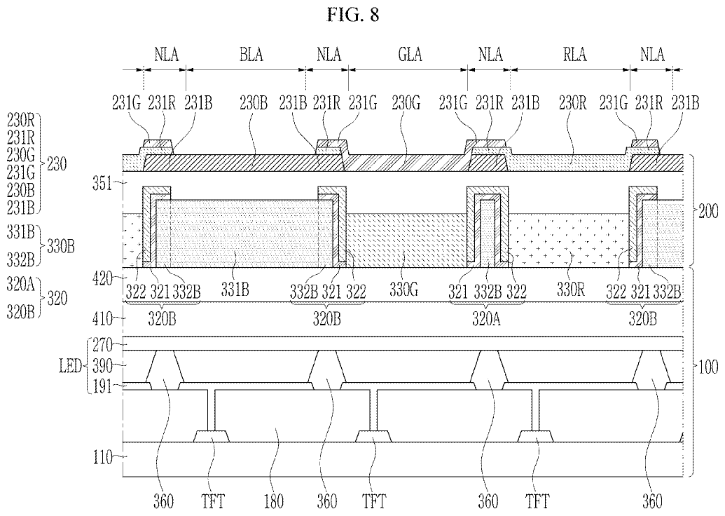

FIG. 8 is a cross-sectional view of a display device according to another embodiment. Referring to FIG. 8, the display device according to the present embodiment is different from FIG. 7 in that it includes a first substrate (110) and does not include a second substrate (210).

In the embodiment of FIG. 8, the description corresponding to the display panel (100) is the same as that of FIG. 7 and thus is omitted.

In the case of the color conversion panel (200) in the present embodiment, a separate second substrate is not included. Instead, the bank (320) is positioned on the buffer layer (420), and closer to the display panel (100) than the color filter layer.

A description of the bank (320) is the same as above.

A detailed description of the same constituent element is omitted.

That is, the bank (320) includes a first bank (320A) and a second bank (320B), each having a different stacked structure.

The second bank (320B) may be positioned adjacent to the blue light emitting region (BLA).

The bank (320) may include a bank transmission layer (332B), a metal layer (321), and a transparent layer (322).

A red color conversion layer (330R), a green color conversion layer (330G), and a transmission layer (330B) are positioned in a region between the banks (320), spaced apart from each other.

The second bank (320B) may be positioned adjacent (and closest) to the blue light emitting region (BLA).

The light transmission layer (331B) of the blue light emitting region (BLA) is integrally formed with the bank transmission layer (332B) included in the bank (320).

In FIG. 8, a red color conversion layer (330R) is positioned in a region overlapping the red light emitting region (RLA).

The red color conversion layer (330R) may convert supplied light into red.

Similarly, the green color conversion layer (330G) is positioned in a region overlapping the green light emitting region (GLA).

The green color conversion layer (330G) may convert supplied light into green.

The color conversion pattern (330R or 330G) is not positioned in a portion corresponding to the blue light emitting region (BLA) in the space partitioned by the bank (320).

Instead, the light transmitting layer (331B) is positioned in a portion corresponding to the blue light emitting region (BLA) in the space partitioned by the bank (320).

The light transmission layer (331B) may include a light scattering material.

The scattering material may be at least one selected from the group consisting of SiO2, BaSO4, Al₂O₃, ZnO, ZrO2, and TiO2.

The light transmission layer (331B) may include a polymer resin and a scattering material included in the polymer resin.

For example, the light transmission layer (331B) may include TiO2, but is not limited thereto.

A low refractive index layer (351) may be positioned on the light transmission layer (331B).

The low refractive index layer (351) may have a refractive index of about 1.2 or less.

The low refractive index layer (351) may include a combination of an organic material and an inorganic material.

A color filter (230) as a color filter layer is positioned on the low refractive index layer (351).

The color filters (230) may include a blue color filter (230B) and a blue dummy color filter (231B), a red color filter (230R) and a red dummy color filter (231R), and a green color filter (230G) and a green dummy color filter (231G).

A description of the green color filter (230G) and the green dummy color filter (231G) above the blue color filter (230B) and the blue dummy color filter (231B), the red color filter (230R) and the red dummy color filter (231R) is the same as that of FIG. 1, so a detailed description thereof is omitted.

In the embodiment of FIG. 7, the blue dummy color filter (231B) of the color filter layer may be positioned farthest from the first substrate (110).

Accordingly, when viewing the display device according to the embodiment of FIG. 8, the blue dummy color filter (231B) of the color filter overlapping body A may be positioned closest to a side of the display device from which an image is viewed, such as by the user.

The blue dummy color filter (231B) of the color filter overlapping body A is positioned closest to the viewing side of the display device since, compared to green or red, blue has the lowest reflectance of all light and can block light (e.g., external light incident to the display device at the viewing side) most effectively, as described above.

In the case of the embodiment of FIG. 8, since only one substrate is included, the total thickness of the entire display device can be reduced.

Therefore, it is advantageous to apply one or more embodiment of a display device to a flexible or foldable display device.

Hereinafter, a method of manufacturing (or providing) a display device according to an embodiment will be described with reference to drawings.

The manufacturing method will be described focusing on the forming process of the bank (320).

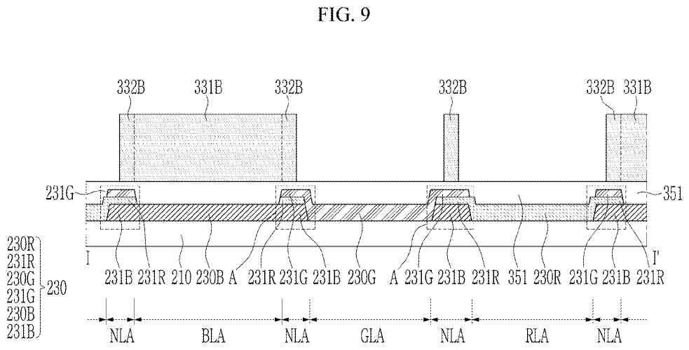

FIG. 9 to FIG. 13 show manufacturing processes of the color conversion panel according to the embodiment of FIG. 1.

Referring to FIG. 9, a color filter (230) as a color filter layer and a low refractive index layer (351) are formed (or provided) on the second substrate (210).

Descriptions of the color filter (230) and the low refractive index layer (351) are the same as those in FIG. 1 to FIG. 4, and thus are omitted.

That is, each color filter pattern among the color filters (230R), (230G), and (230B) includes a main portion and a dummy color filter (231R), (231G), and (231B) which is positioned on the same layer as the main portion. A respective main portion of color filter and one or more of the dummy color filter together form a color filter overlapping body (A) as a stacked structure.

Referring to FIG. 9, a transmission layer (330B) is formed on the low refractive index layer (351).

The transmission layer (330B) includes a light transmission layer (331B) and a bank transmission layer (332B).

The light transmission layer (331B) may be formed in the blue light emitting region (BLA), and the bank transmission layer (332B) may be formed in the non-emission region (NLA). The bank transmission layer (332B) may be provided in plural spaced apart from each other along the second substrate (210).

As shown in FIG. 9, the light transmission layer (331B) and the bank transmission layer (332B) may be integrally formed and connected to each other.

A description of the transmission layer (330B) is omitted since it is the same as described above.

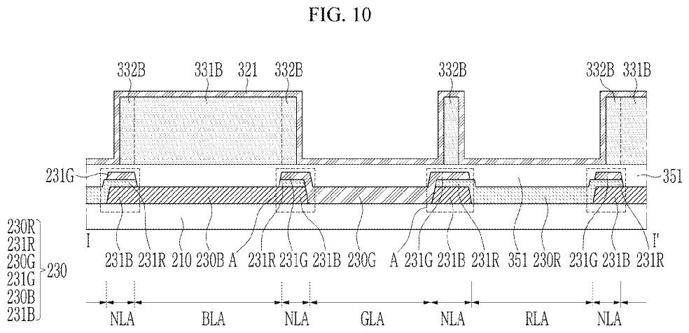

Next, referring to FIG. 10, a material layer for providing a metal layer (321) is formed.

As shown in FIG. 10, the material layer (as a preliminary metal layer) for providing the metal layer (321) is formed on the entire surface of the low refractive index layer (351) and the transmission layer (330B).

That is, the metal layer (321) covers the top surface of the low refractive index layer (351), and the top surface and side surfaces of the transmission layer (330B).

A description of the metal layer (321) is omitted since it is the same as described above.

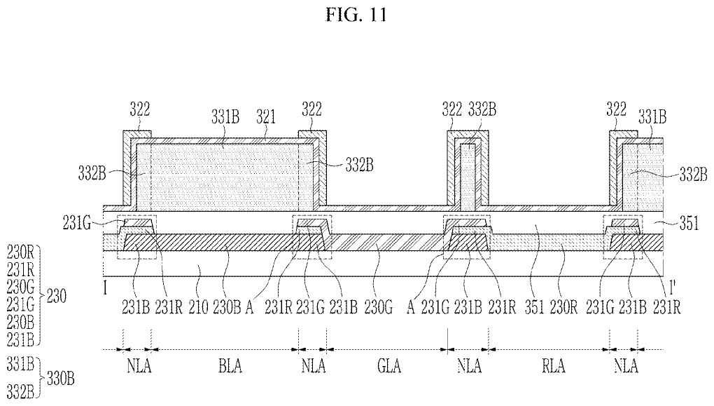

Next, referring to FIG. 11, a transparent layer (322) is formed.

In this case, the transparent layer (322) is formed in the non-emission region (NLA).

The transparent layer (322) may be formed to overlap the top and side surfaces of the bank transmission layer (332B).

The transparent layer (322) may cover the upper surface and both side surfaces of the bank transmission layer (332B).

However, as shown in FIG. 11, in the non-emission region (NLA) adjacent to the blue light emission region (BLA), the transparent layer (322) may overlap a partial upper surface region and one side surface of the bank transmission layer (332B).

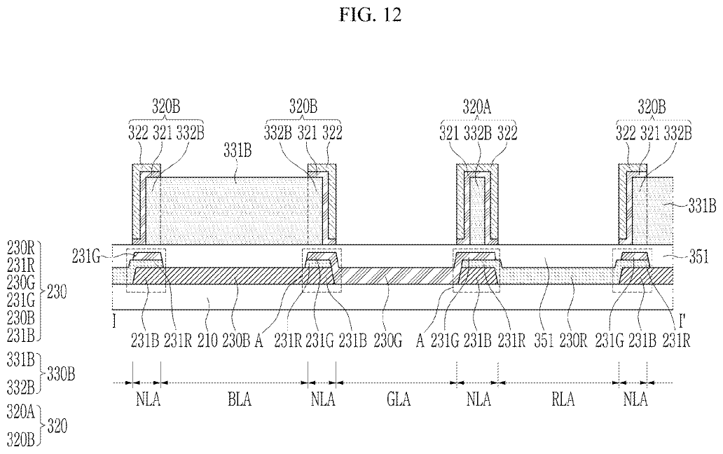

Next, referring to FIG. 12, the preliminary metal layer for providing the metal layer (321) is etched.

In this case, the etching may be performed using the transparent layer (322) as a mask, and material for forming the metal layer (321) that does not overlap with the transparent layer (322) may be etched.

Accordingly, the edge of the transparent layer (322) coincides with the edge of the metal layer (321).

That is, the edge of the transparent layer (322) and the edge of the metal layer (321) may be aligned with each other.

As shown in FIG. 12, the metal layer (321) positioned in each of the light emitting regions ((BLA), (GLA), (RLA)) may be etched by this etching process. The etching of the preliminary metal layer at the light emitting regions exposes the transmission layer (330B) to outside of both the metal layer (321) and the transparent layer (322).

Accordingly, light may be incident or emitted from the light emitting region, at the light emission opening defined between the aligned edges of the transparent layer (322) and edge of the metal layer (321).

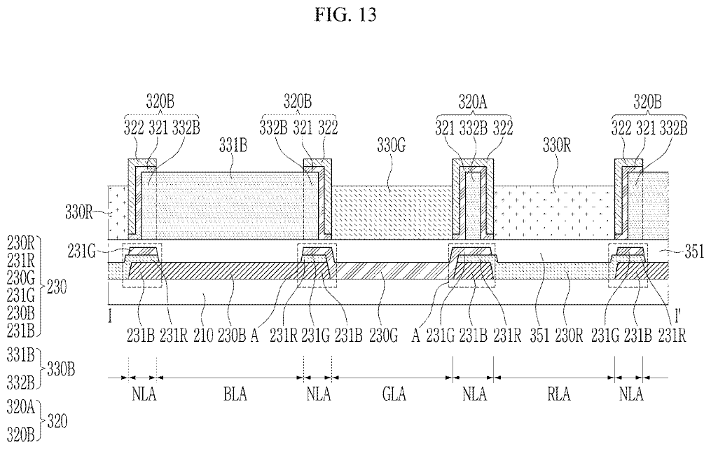

Next, referring to FIG. 13, a red color conversion layer (330R) is formed in the red light emitting region (RLA), and a green color conversion layer (330G) is formed in the green light emitting region (GLA).

In this case, the red color conversion layer (330R) and the green color conversion layer (330G) may be formed by an inkjet process.

An upper surface of the transparent layer (322) of the bank (320) may have hydrophobic property, and a side surface of the transparent layer (322) may have hydrophilic property.

Therefore, ink as a color conversion material for providing each color conversion layer is injected into the bank (320) without spreading out of the bank (320) and can spread within the bank (320).

That is, in the method of providing the display device according to the present embodiment, the bank (320) includes a bank transmission layer (332B), a metal layer (321) and a transparent layer (322), and the light transmission layer (331B) of the blue light emitting region (BLA), the bank transmission layer (332B) of the bank (320) are formed in the same process.

Therefore, the forming of the light transmission layer (331B) and the bank transmission layer (332B) in a same process is economical since the manufacturing process can be reduced.

In addition, since the metal layer (321) is etched using the transparent layer (322) as a mask, the processes of the method can be reduced. Since the metal layer (321) is positioned inside the bank (320) to reflect light incident to the bank (320), light efficiency can be increased.

When the color conversion panel (200) thus manufactured is combined with the display panel (100) which generates an image and/or provides incident light, a display device according to the embodiment of FIG. 7 may be manufactured.

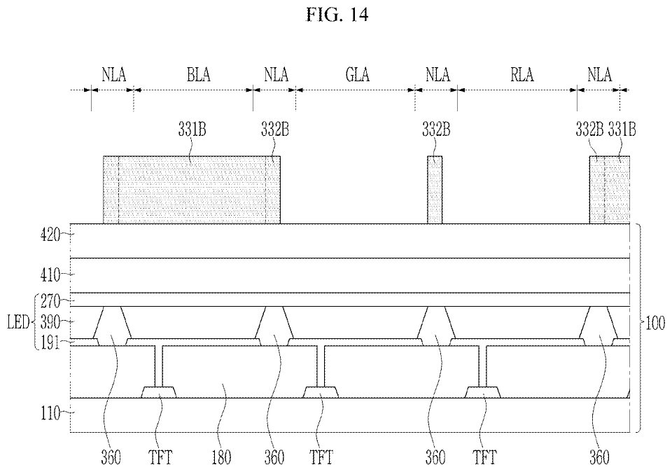

FIG. 14 to FIG. 18 illustrate manufacturing processes of a display device according to the embodiment of FIG. 8.

FIG. 14 to FIG. 18 are the same as the embodiments of FIG. 9 to FIG. 13 except that they are formed on the display panel (100).

Referring to FIG. 14, the display panel (100) is prepared and provides a base substrate on which layers of the color conversion panel (200) are formed.

Since the description of the display panel (100) is the same as that of FIG. 7 and FIG. 8, it is omitted.

In addition, detailed descriptions of the same constituent elements will be omitted below.

Referring to FIG. 14, a transmission layer (330B) is formed on the buffer layer (420).

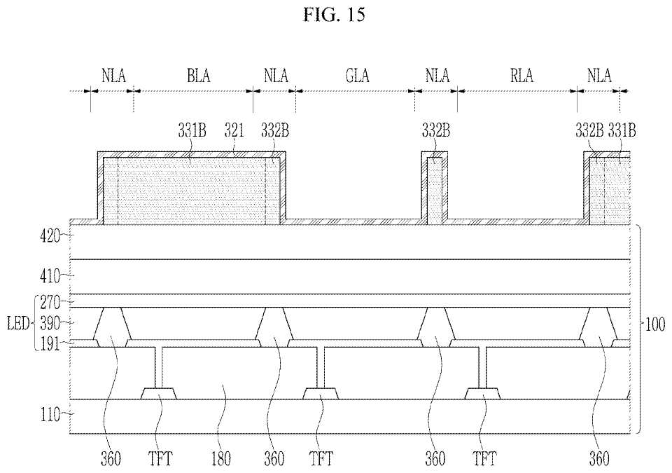

The transmission layer (330B) includes a light transmission layer (331B) positioned in the blue light emitting region (BLA) and a bank transmission layer (332B) positioned in the non-emission region (NLA), as shown in FIG. 14. The transmission layer (331B) and the bank transmission layer (332B) may be integrally formed and connected to each other. A description of the transmission layer (330B) is the same as described above, so it is omitted. Next, referring to FIG. 15, a preliminary metal layer for forming a metal layer (321) is formed.

As shown in FIG. 15, the metal layer (321) is formed on the entire surface of the buffer layer (420) and the bank transmission layer (332B).

That is, the metal layer (321) covers the upper surface of the buffer layer (420), and the upper and side surfaces of the bank transmission layer (332B).

A description of the metal layer (321) is omitted because it is the same as described above.

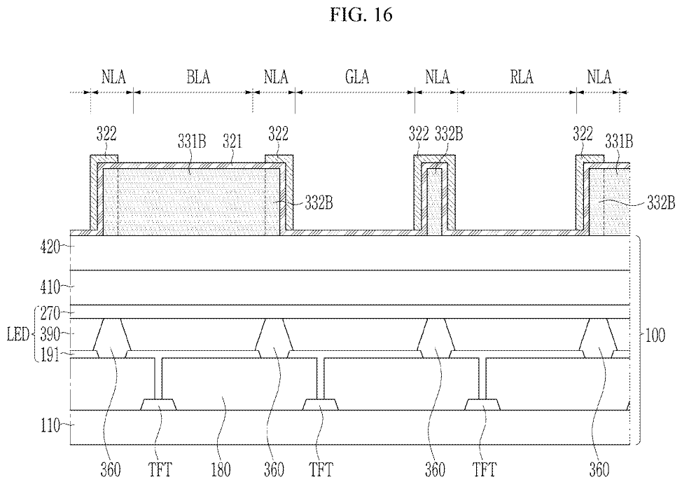

Next, referring to FIG. 16, a transparent layer (322) is formed.

In this case, the transparent layer (322) is formed in the non-emission region (NLA).

The transparent layer (322) may be formed to overlap the upper and side surfaces of the bank transmission layer (332B).

The transparent layer (322) may cover the upper surface and both side surfaces of the bank transmission layer (332B).

However, as shown in FIG. 16, in the non-emission region (NLA) adjacent to the blue light emission region (BLA), the transparent layer (322) may cover only a partial upper surface region and one side surface of the bank transmission layer (332B).

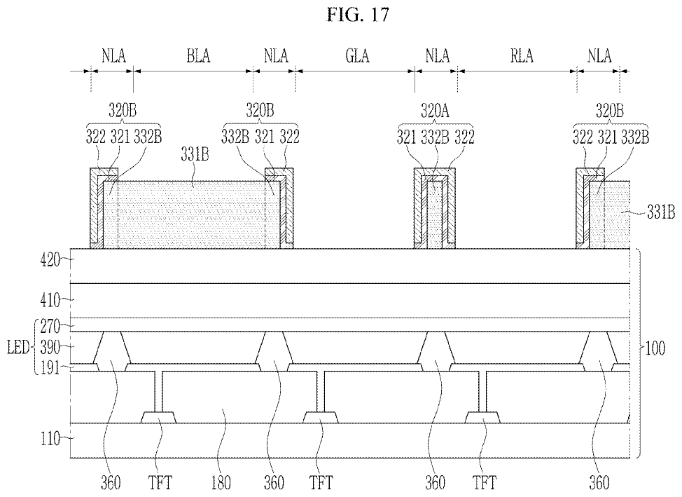

Next, referring to FIG. 17, the metal layer (321) is etched.

In this case, the etching may be performed using the transparent layer (322) as a mask, and the metal layer (321) that does not overlap with the transparent layer (322) may be etched.

As shown in FIG. 17, the metal layer (321) positioned in each of the light emitting regions ((BLA), (GLA), and (RLA)) may be etched by this etching process.

Accordingly, light emitted from the light emitting device of the display panel (100) may be incident to each of the light emitting regions ((BLA), (GLA), and (RLA)).

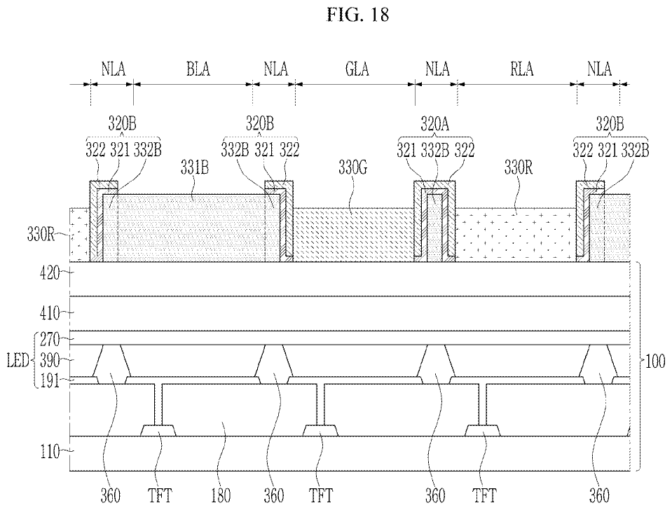

Next, referring to FIG. 18, a red color conversion layer (330R) is formed in the red light emitting region (RLA), and a green color conversion layer (330G) is formed in the green light emitting region (GLA).

In this case, the red color conversion layer (330R) and the green color conversion layer (330G) may be formed by an inkjet process.

An upper surface of the transparent layer (322) of the bank (320) may have hydrophobic property, and a side surface of the transparent layer (322) may have hydrophilic property.

Therefore, ink including each color conversion layer is injected into the bank (320) without spreading out of the bank (320) and can spread within the bank (320).

That is, in the manufacturing method of the display device according to the present embodiment, the bank (320) includes a transmission layer (330B), a metal layer (321), a transparent layer (322), and the light transmission layer (331B) of the blue light emitting region (BLA). During the forming process, the bank transmission layer (332B) of the second bank (320B) is formed through the same process.

Therefore, the method is economical because the manufacturing process can be reduced.

In addition, since the metal layer (321) is etched using the transparent layer (322) as a mask, the process can be reduced, and since the metal layer (321) is positioned inside the bank (320) to reflect, light efficiency can be increased.

Although not shown, after FIG. 18, a low refractive index layer (351) is provided on the red color conversion layer (330R), the green color conversion layer (330G), and the light transmission layer (331B). The color filter (230) is provided on the refraction layer (351) to provide the display device of FIG. 8.

In an embodiment, a color conversion panel includes a first light emitting region (GLA or RLA) and a second light emitting region (BLA) of a substrate, a plurality of banks (320) on the substrate and partitioning the first light emitting region and the second light emitting region, each bank among the plurality of banks including a bank light transmission layer (332B), a metal layer on the bank light transmission layer and a transparent layer on the metal layer, a color conversion layer (330G or 330R) in the first light emitting region, and a light transmission layer (331B) in the second light emitting region. The bank light transmission layer and the light transmission layer are respective portions of a same material layer on the substrate.

The plurality of banks includes a first bank (320A) and a second bank (320B) on opposing sides of the color conversion layer (330G and 330R), the second bank being closer to the light transmission layer (331B) than the first bank, the light transmission layer (331B) extends out of the second light emitting region and toward the color conversion layer to define an extended portion (332B) of the light transmission layer, and the extended portion of the light transmission layer includes the bank light transmission layer.

Within the first bank (320A), the metal layer covers an outer surface of the bank light transmission layer (332B), and the transparent layer covers an outer surface of the metal layer. Within the second bank (320B), the metal layer covers an upper surface and a side surface of the bank light transmission layer (332B) which faces the color conversion layer, and the transparent layer covers an outer surface of the metal layer.

In an embodiment, a method of providing a display device includes providing on a substrate, a plurality of banks (320) partitioning a first light emitting region and a second light emitting region of the display device, and providing a plurality of light transmission patterns (331B and 332B) spaced apart from each other along the substrate, the light transmission patterns including a plurality of bank light transmission layers (332B) respectively between the first light emitting region and the second light emitting region, and a light transmission layer (331B) in the second light emitting region (BLA). The providing of the plurality of banks includes providing a metal material layer on the bank light transmission layers (332B) and the light transmission layer (331B), providing a transparent layer on the metal material layer to respectively expose a portion of the metal material layer which corresponds to the first light emitting region and the second light emitting region to outside the transparent layer, and etching the portion of the metal material layer which is exposed, using the transparent layer as a mask, to form the plurality of banks each including a bank light transmission layer among the plurality of bank light transmission layers, a metal layer, and the transparent layer.

In an embodiment, a display device includes a plurality of light emitting regions (GLA, RLA, BLA) including a first light emitting region (GLA or RLA) and a second light emitting region (BLA), a display panel (100) a first substrate, a plurality of partition walls (360) respectively between the plurality of light emitting regions, along the first substrate, and an emission layer between the partition walls, and a color conversion panel (200) facing the display panel (100), the color conversion panel including a second substrate, a plurality of banks on the second substrate and respectively corresponding to the plurality of partition walls, each bank among the plurality of banks including a bank light transmission layer (332B), a metal layer on the bank light transmission layer, and a transparent layer on the metal layer, a color conversion layer (330R or 330G) in the first light emitting region, and a light transmission layer in the second light emitting region. The bank light transmission layer (332B) and the light transmission layer (331B) are respective portions of a same material layer on the second substrate.

A detailed description of the same constituent element is omitted.

Although the embodiments of the present invention have been described in detail above, the scope of the present invention is not limited thereto, and various modifications and improvements that would be employed by a skilled artisan using the basic concepts of the present invention defined in the following claims are also included in the scope of the present invention.

What is claimed is:

1. A color conversion panel, comprising:
a substrate comprising a first light emitting region and a second light emitting region;
a plurality of banks on the substrate and partitioning the first light emitting region and the second light emitting region, each bank among the plurality of banks comprising:
a bank light transmission layer;
a metal layer on the bank light transmission layer; and
a transparent layer on the metal layer;
a color conversion layer in the first light emitting region; and
a light transmission layer in the second light emitting region,
wherein the bank light transmission layer and the light transmission layer are respective portions of a same material layer on the substrate.

2. The color conversion panel of claim 1, wherein within the each bank, the bank light transmission layer is closer to the substrate than the transparent layer.

3. The color conversion panel of claim 1, wherein
the plurality of banks includes a first bank and a second bank on opposing sides of the color conversion layer, the second bank being closer to the light transmission layer than the first bank,
the light transmission layer extends out of the second light emitting region and toward the color conversion layer to define an extended portion of the light transmission layer, and
the extended portion of the light transmission layer includes the bank light transmission layer.

4. The color conversion panel of claim 1, wherein the metal layer of the each bank does not overlap the first light emitting region or the second light emitting region along a thickness direction of the color conversion panel.

5. The color conversion panel of claim 1, wherein a thickness of the metal layer is about 100 angstroms to about 1000 angstroms.

6. The color conversion panel of claim 1, wherein a thickness of the transparent layer is about 1 micrometer to about 5 micrometers.

7. The color conversion panel of claim 1, wherein
the plurality of banks includes a first bank and a second bank on opposing sides of the color conversion layer, the second bank being closer to the light transmission layer than the first bank, and
within the first bank:
the metal layer covers an outer surface of the bank light transmission layer, and
the transparent layer covers an outer surface of the metal layer.

8. The color conversion panel of claim 1, wherein
the plurality of banks includes a first bank and a second bank on opposing sides of the color conversion layer, the second bank being closer to the light transmission layer than the first bank, and
within the second bank:
the metal layer covers an upper surface and a side surface of the bank light transmission layer which faces the color conversion layer, and
the transparent layer covers an outer surface of the metal layer.

9. The color conversion panel of claim 8, wherein within the second bank, ends of the metal layer and ends of the transparent layer are aligned with each other.

10. The color conversion panel of claim 1, wherein
the first light emitting region emits red light or green light, and
the second light emitting region emits blue light.

11. A method of providing a display device, the method comprising:
providing on a substrate, a plurality of banks partitioning a first light emitting region and a second light emitting region of the display device; and
providing a plurality of light transmission patterns spaced apart from each other along the substrate, the light transmission patterns including a plurality of bank light transmission layers respectively between the first light emitting region and the second light emitting region, and a light transmission layer in the second light emitting region;
wherein the providing of the plurality of banks comprises:
providing a metal material layer on the bank light transmission layers and the light transmission layer;
providing a transparent layer on the metal material layer to respectively expose a portion of the metal material layer which corresponds to the first light emitting region and the second light emitting region to outside the transparent layer; and
etching the portion of the metal material layer which is exposed, using the transparent layer as a mask, to form the plurality of banks each including a bank light transmission layer among the plurality of bank light transmission layers, a metal layer, and the transparent layer.

12. The method of claim 11, further comprising providing a color conversion layer in the first light emitting region.

13. The method of claim 11, wherein
the plurality of banks includes a first bank and a second bank on opposing sides of the first light emitting region, the second bank being closer to the light transmission layer than the first bank,
the light transmission layer extends out of the second light emitting region and toward the first light emitting region to define an extended portion of the light transmission layer, and
the extended portion of the light transmission layer includes the bank light transmission layer of the second bank, and
within the second bank:
the metal layer covers an upper surface and a side surface of the bank light transmission layer which is closest to the first light emitting region, and
the transparent layer covers an outer surface of the metal layer.

14. The method of claim 11, wherein
the plurality of banks includes a first bank and a second bank on opposing sides of the first light emitting region, the second bank being closer to the light transmission layer than the first bank, and
within the first bank:
the metal layer covers an outer surface of the bank light transmission layer, and
the transparent layer covers an outer surface of the metal layer.

15. The method of claim 11, further comprising prior to the providing of the plurality of light transmission patterns spaced apart from each other along the substrate, providing a color filter on the substrate.

16. The method of claim 11, further comprising prior to the providing of the plurality of light transmission patterns spaced apart from each other along the substrate, providing on the substrate, a transistor and a light emitting device which is connected to the transistor.

17. A display device, comprising:
a plurality of light emitting regions comprising a first light emitting region and a second light emitting region;
a display panel comprising:
a first substrate;
a plurality of partition walls respectively between the plurality of light emitting regions, along the first substrate; and
an emission layer between the partition walls; and
a color conversion panel facing the display panel, the color conversion panel comprising:
a second substrate;
a plurality of banks on the second substrate and respectively corresponding to the plurality of partition walls, each bank among the plurality of banks comprising:
a bank light transmission layer;
a metal layer on the bank light transmission layer; and
a transparent layer on the metal layer;
a color conversion layer in the first light emitting region; and
a light transmission layer in the second light emitting region,
wherein the bank light transmission layer and the light transmission layer are respective portions of a same material layer on the second substrate.

18. The display device of claim 17, wherein within the each bank among the plurality of banks:
the metal layer covers an outer surface of the transparent layer,
the metal layer does not overlap the first light emitting region or the second light emitting region.

19. A display device, comprising:
a first substrate comprising a plurality of light emitting regions comprising a first light emitting region and a second light emitting region;
a plurality of partition walls on the first substrate;
an emission layer between the partition walls;
a plurality of banks respectively overlapping the partition walls;
a color conversion layer in the first light emitting region; and
a light transmission layer in the second light emitting region,
wherein
each bank among the plurality of banks comprises:
a bank light transmission layer;
a metal layer on the bank light transmission layer; and
a transparent layer on the metal layer, and
the bank light transmission layer and the light transmission layer are respective portions of a same material layer.

20. The display device of claim 19, wherein within the each bank among the plurality of banks:
the metal layer covers an outer surface of the transparent layer,
the metal layer does not overlap the first light emitting region or the second light emitting region.
